(19) United States
(12) Patent Application Publication
(10) Pub. No.: US 2005/0205969 A1
(43) Pub. Date: Sep. 22, 2005

(54) Charge trap non-volatile memory structure for 2 bits per transistor

(75) Inventors: Yoshi Ono, Camas, WA (US); John F. Conley JR., Camas, WA (US); Pooran Chandra Joshi, Vancouver, WA (US)

Correspondence Address: DAVID C RIPMA, PATENT COUNSEL;SHARP LABORATORIES OF AMERICA, 5750 NW PACIFIC RIM BLVD, CAMAS, WA, 98607, US

(73) Assignee: Sharp Laboratories of America, Inc.

(21) Appl. No.: 10/805,158

(22) Filed: Mar. 19, 2004

(51) Int. Cl. H01L 23/58; H01L 21/336

(52) U.S. Cl. 257/645; 257/651; 438/288

(57) ABSTRACT

The present invention discloses a non-volatile memory cell structure utilizing a charge trapping high-k dielectric in the place of the triple film stack (tunnel dielectric layer/charge trapping layer/blocking layer). The charge trapping characteristic of the high-k dielectric can be further improved by exposing the high-k dielectric layer to an treatment process such as a plasma exposure using excited state oxygen (e.g. oxygen plasma) ambient. By using a single layer as the charge trapping gate dielectric, the present invention presents a simple and inexpensive solution that permits device scaling to very small dimensions, together with the ease of device fabrication processes. The present invention also discloses the fabrication process for the charge trapping high-k gate dielectric non-volatile memory cell structure, applicable to bulk device, TFT device or SOI device.

### BACKGROUND OF THE INVENTION

This invention relates generally to semiconductor devices and nonvolatile memory devices, and more particularly to non-volatile multi-bit charge trap memory cell structures and methods of fabrication.

Non-volatile memory devices retain information stored in their memory cells even when the power is turned off. One class of non-volatile memory devices that evolves from read-only-memory (ROM) and programmable-read-only memory (PROM) is erasable-programmable-read-only memory (EPROM), which typically requires ultraviolet radiation to erase the memory contents, and electrically-erasable-programmable-read-only-memory (EEPROM), which can be programmed, read, and erased electrically. Flash EEPROM devices are similar to EEPROM devices with the additional characteristic that the contents of all the memory's cells can be erased simultaneously through the use of an electrical erase signal.

The basic component of a non-volatile EEPROM memory device is an isolated charge trapping gate layer that retains the charge even in the absence of power. Charging and discharging this charge trapping gate layer would change the channel conductivity of the memory device: a charged gate resulting in high current flow (representing one memory state), and a discharged gate resulting in no current flow (representing another memory state). The onset of current flow is termed the threshold voltage and can be used to measure the states of the transistor.

Currently there are two types of charge storage in the gate stack of a non-volatile EEPROM memory device: a conductive charge trapping layer (called a floating gate device) or a non-conductive charge trapping layer (called NROM, nitride read only memory, due to the fact that a typical charge trapping layer is made of silicon nitride, or MONOS, metal-oxide-nitride-oxide-silicon, due to the fact that the charge trapping layer is a silicon nitride sandwiched between two silicon oxide insulator layers). The structures of a floating gate and a NROM memory cell are essentially the same with the only difference being the conductivity or non-conductivity of the charge trapping layer. Since the charge trapping layer in the floating gate design is conductive, a single defect in the bottom sandwiched insulator layer can discharge the entire memory content. Thick dielectric film or high quality dielectric film is therefore required to improve the reliability of the floating gate memory devices. Since the thick dielectric layer may induce several disadvantages, for example, fluctuation of threshold voltage, high operating voltage or high power consumption, high quality dielectric film is essential in floating gate memory cell fabrication. Since the charge trapping layer is non conducting in NROM design, NROM memory cell stores charge in spatially isolated traps of the charge trapping layer, thus offering the possibility of multi-bit memory storage. FIG. 1 shows a typical prior art NROM memory transistor having a gate stack of a tunnel gate dielectric 11 (typically silicon oxide), a non-conducting charge trapping layer 12 (typically silicon nitride) over the tunnel gate dielectric 11, a top dielectric 13 (typically silicon oxide) over the charge trapping layer 12, and a conductive control gate electrode 14 over the top dielectric 13 with the whole gate stack positioned over a crystalline silicon substrate.

The typical material for the charge trapping layer in NROM or MONOS devices is a multilayer of Oxide-Nitride-Oxide (ONO). Because of the requirement of charge storage within the ONO structure for proper functionality of the memory cell, the memory transistor fabrication process typically requires a high quality ONO structure. The oxide layer should not be too thick because otherwise the required programming voltage would increase undesirably. But the oxide layer also should not be too thin, or of poor quality because otherwise charge retention time would decrease undesirably since the charge tends to leak. In particular, the ONO layer must be carefully fabricated to insure proper charge isolation by avoiding the creation of interface states that could provide charge leakage paths within the ONO layer. Thus, it is important to achieve high integrity of the silicon oxide insulator dielectric in order to improve memory reliability, either by high quality oxide film, or by insulator film engineering such as silicon nitrided oxide (SiON) film.

The use of alternative dielectric layers in place of the insulator layers in NROM memory device is known, for example, high dielectric constant (high-k) zirconium oxide layer formed on the substrate can reduce control voltage and increase current drivability, exhibiting low subthreshold swing and well on/off characteristics, leading to the reduction of defect density and improvement of device reliability.

However, prior art high dielectric constant materials only seek to replace the oxide layers of the ONO gate stack, not the charge trapping layer silicon nitride itself. Since the silicon nitride is not the perfect material for charge trapping in localized region because of the lateral dispersion of charge due to the self generated lateral electric field and the lateral diffusion and dispersion of charge in response to subsequent high temperature processes, alternative material for the charge trapping layer could lead to reliability improvement and simplified fabrication process.

### BRIEF SUMMARY OF THE INVENTION

The present invention discloses a non-volatile memory cell structure utilizing a charge trapping high-k dielectric in the place of the triple film stack (tunnel dielectric layer/charge trapping layer/blocking layer). The charge trapping characteristic of the high-k dielectric can be further improved by subjecting the high-k dielectric layer to a treatment process such as a plasma exposure using an excited state oxygen (e.g. oxygen plasma) ambient. By using a single layer as the charge trapping gate dielectric, the present invention presents a simple and inexpensive solution that permits device scaling to very small dimensions, together with the ease of device fabrication processes. The dielectric property of the charge trapping layer also permits multi-bit information storage per transistor.

The high-k dielectric material is preferably aluminum oxide, hafnium oxide, zirconium oxide, titanium oxide, aluminum nitride, hafnium nitride, or any alloys of these materials such as aluminum hafnium oxide, aluminum oxynitride. The irradiation exposure is preferably oxygen plasma or nitrogen plasma to induce trapping centers in the high-k dielectric.

The present invention also discloses the fabrication process for the charge trapping high-k dielectric non-volatile memory cell structure, applicable to bulk device, TFT device or SOI device.

### BRIEF DESCRIPTION OF THE DRAWINGS

FIG. 1 shows the schematic of prior art NROM non-volatile memory transistor cell employing triple film stack (tunnel dielectric layer/charge trapping layer/blocking layer).

FIG. 2 shows the schematic of the present invention memory cell utilizing a single layer charge trapping high-k gate dielectric.

FIG. 3 shows the two-bit operation of the present invention memory cell.

FIG. 4 shows the cross section of the fabricated memory device.

FIG. 5 shows the cyclic data showing 2-bit states of the fabricated device.

FIG. 6 shows the memory state separation as a function of programming pulse width.

FIG. 7 shows the independency of 2 bits in 2-bit memory cell.

### DETAILED DESCRIPTION OF THE PREFERRED EMBODIMENTS

The present invention discloses a simple and inexpensive NROM structure that permits device scaling to very small dimensions. The current manufactured flash EEPROMs are difficult to scale due to non-scalability of the tunnel oxide and susceptibility to high leakage and defects at the lower thickness limit. Some MONOS and SONOS non-volatile memories employed charge storage on the gate sidewall (spacer) for 2-bit information storage, but the deposition and etching of the spacer along with the position with respect to the drain/channel or source/channel junctions are critical processes. The present invention discloses a film stack that is easy to deposit and a structure that does not rely on such critical processes.

The non-volatile memory cell of the present invention is a charge trapping transistor having a charge trapping high-k dielectric in the place of the triple film stack (tunnel dielectric layer/charge trapping layer/blocking layer). Typically, as-deposited dielectric films almost always exhibit some charge trapping characteristic, normally associated with broken bonds, lattice damage, or impurity incorporation, etc. The charge trapping sites can be much higher in high-k dielectric layer as compared to silicon dioxide mainly due to process limitation, novel precursors, and less optimization and process experiences. Therefore as-deposited high-k dielectric can be used as charge trapping dielectric layer. The charge trapping characteristic of the high-k dielectric layer can be further improved by subjecting the high-k dielectric layer to a treatment process. The treatment process is designed to increase the charge trapping sites in the high-k dielectric layer, for example by generating broken bonds, by creating lattice damage, or by introducing impurity sites. The treatment process is preferably plasma exposure or ion implantation exposure, exposing the high-k dielectric layer to energetic charges and neutral species. However, the treatment process is not limited to these processes but also encompasses any process that potentially can increase the charge trapping sites in the high-k dielectric material.

By using a single layer as the charge trapping gate dielectric, the present invention presents a simple and inexpensive solution that permits device scaling to very small dimensions, together with the ease of device fabrication processes. By forming a single layer charge trapping dielectric according to the present invention, a memory cell having a low defect density, high coupling ratio, high dielectric constant, better time dependent dielectric breakdown and less interface traps, resulting in high performance and high reliability can be achieved.

High-k dielectric is highly desirable for a gate dielectric since the speed of a field effect transistor (FET) is directly proportional to the response of a gate dielectric, which, in turn, is directly proportional to its dielectric constant k. The primary material for gate dielectrics is silicon dioxide (SiO₂) with a dielectric constant of about 4. Silicon dioxide films of less than 1.5 nm generally cannot be used due to the high leakage from the direct tunneling currents and other fabrication and reliability concerns such as boron penetration, and charge injection damage. Many high dielectric constant dielectric materials (high-k dielectric) have been investigated as possible replacements for silicon dioxide but a suitable replacement has still not been found because of the many other stringent requirements such as low leakage current, formation of a good interface with silicon substrate, low thermal budget for the fabrication process, and device high channel mobility. The high-k dielectric material for the present invention charge trapping high-k dielectric memory cell structure is preferably aluminum oxide (Al₂O₃), hafnium oxide (HfO₂), zirconium oxide (ZrO₂), titanium oxide (TiO₂), tantalum oxide (Ta₂O₅), aluminum nitride (AlN), hafnium nitride (HfN), hafnium silicate (HfSiO₄), zirconium silicate (ZrSiO₄) or any alloys of these materials such as aluminum hafnium oxide (AlHfO), aluminum oxynitride (AlON), hafnium silicon oxynitride (HfSiON), zirconium silicon oxynitride (ZrSiON).

The treatment process can be a plasma exposure, preferably oxygen plasma or nitrogen plasma to induce trapping centers in the high-k dielectric layer. Depending on the high-k film properties and qualities, the ionized species generated from the plasma ambient might be sufficient to induce trapping centers, and therefore many gases can be used in the plasma besides oxygen and nitrogen, such as ozone, helium, argon, air, hydrogen, and any non-reactive gases. Furthermore, the plasma ambient can also contain reactive gases such as silane, dichlorosilane, which could induce trapping centers together with modifying the film composition. The plasma generation can be parallel plate plasma or preferably inductive coupled plasma (ICP) for higher ion density. Typical plasma exposure time varies from 10 seconds to 100 seconds, with a preferred 20 seconds exposure time.

The treatment process can also be ion implantation or plasma immersion ion implantation. As with plasma exposure, ion implantation exposes the high-k dielectric layer to energetic ions, and as a result generating significant lattice damage, together with impurity incorporation. The traditional technique of single energy beamline ion implantation can be used with various ion species such as ionized molecular oxygen, ionized atomic oxygen, ionized molecular hydrogen (H₂+), ionized atomic hydrogen (H+), helium, nitrogen, helium, silicon, argon or any combinations thereof. The implantation process can also be plasma immersion ion implantation process which has a broader implantation zone due to different ion species from the plasma implanted to different depth. Plasma immersion ion implantation is an emerging technology, which promises high dose implantation at low cost and could potentially be used in the present invention process. Typical ion implantation energy is between 10 to 300 keV with a dose of between 10¹⁴ to 10¹⁷.

The high-k dielectric material which can be used in the present invention is not limited to the above mentioned high-k dielectric materials. Other high-k materials may be suitably used in the present invention, such as barium titanate (BaTiO₃), strontium titanate (SrTiO₃), lead titanate (PbTiO₃), barium strontium titanate (BST) (Ba₁₋ₓSrₓTiO₃), cesium oxide (CeO₂), lanthanum oxide (La₂O₃), tungsten oxide (WO₃), yttrium oxide (Y₂O₃), bismuth silicon oxide (Bi₄Si₂O₁₂), barium strontium oxide (Ba₁₋ₓSrₓO₃), lanthanum aluminum oxide (LaAlO₃), lead zirconate (PbZrO₃), PZN (PbZnₓNb₁₋ₓO₃), and PST (PbScₓTa₁₋ₓO₃), PMN (PbMgₓNb₁₋ₓO3), ferroelectric high-k dielectric materials such as lead zirconium titanate, lead lanthanum titanate, strontium bismuth tantalate, bismuth titanate, strontium titanate, lead zirconium titanate (PZT (PbZrₓTi₁₋ₓO₃)) and barium zirconium titanate. Furthermore, other high-k dielectric materials known in the art also may be used in the present invention.

The high-k dielectric materials disclosed in the present invention are not limited to their exact stoichiometry of the chemical formula as stated but also includes non-stoichiometric variations. For example, hafnium oxide (or HfO₂) has an exact stoichiometry of one hafnium bonded with two oxygens. As used in the present invention, the term “hafnium oxide” or “HfO₂” may include variants of stoichiometric HfO₂, which may be referred to as HfₓO_{y} in which either of x or y vary by a small amount from their stoichiometric values. For example, x may vary from about 0.75 to about 1.5, and y may vary from about 1.5 to about 3.

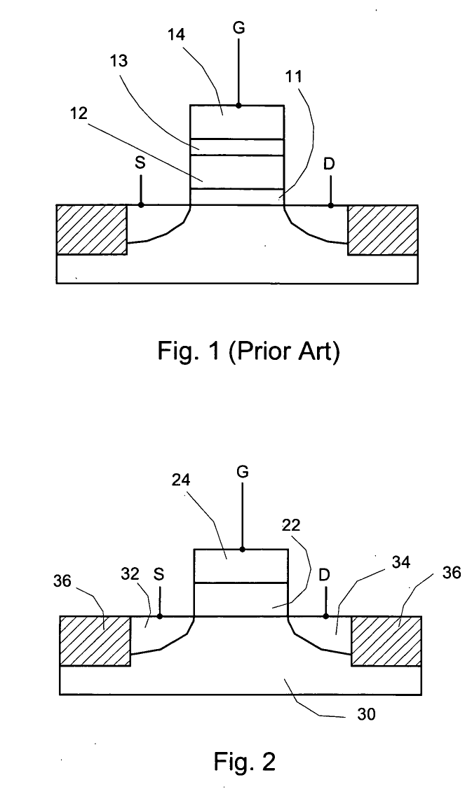

The charge trapping transistor of the present invention is shown in FIG. 2. The gate stack of the present invention comprises a gate electrode 24, a charge trapping high-k dielectric layer 22, positioning on a silicon substrate 30, and disposed between the source 32 and drain 34 regions having a high concentration of dopants. The memory transistor is isolated by the isolation trenches 36. The charge trapping high-k dielectric layer 22 is a high-k dielectric layer, exposing to plasma oxygen ambient to generate trapping centers. Thus the triple gate stack of blocking oxide/charge trapping nitride/tunnel oxide multilayer of the prior arts (shown as multilayer 11/12/13 in FIG. 1) is replaced in the present invention with a single layer of charge trapping high-k dielectric 22.

For memory operation, NROM memory cell is programmed by a hot electron injection method or a Fowler-Nordheim (FN) tunnel current charge injection method. In the hot electron injection method, a high control gate voltage and a high drain voltage are applied to the memory transistor to cause impact ionization, and a generated hot electron is drawn into a gate electrode side, so that an electric charge is injected into the charge trapping layer of the memory transistor. On the other hand, in the FN current system, a high voltage is applied between a control gate electrode and a substrate to cause a FN tunnel current to flow, so that an electric charge is injected into the charge trapping layer. The main disadvantage of Fowler-Nordheim programming is the need of a high electric field, which is crucial to determine device reliability and endurance characteristics. The Fowler-Nordheim programming also takes a longer programming time.

After programming, the memory cell can be read. The read is actually a measurement of the threshold voltage. By convention, the gate threshold voltage is measured by applying a constant voltage to the drain and a ramping voltage to the gate while measuring the channel current. The gate voltage that produces about 1 pA channel current is called the threshold voltage. The reading can be performed in the same direction or in reverse direction as programming with the reverse direction reading resulting in faster memory operation.

The act of discharging the trapped charges of a flash memory cell is called the erase function. The erase function can be carried out by a Fowler-Nordheim tunneling of holes from the conductive control gate through the top oxide to the charge trapping layer, or by removing the electrons from the charge trapping layer to the gate or to the source or drain. Fowler-Nordheim tunneling current of holes or electrons occurs by applying appropriate polarity voltage between the gate electrode and either the source or the drain.

Due to the non-conductivity of the charge trapping layer, and thus the localized nature of charge storage within an insulating charge trapping layer, multiple regions of stored charge within an insulating charge trapping layer can be designed. This type of non-volatile memory device is known as multi-bit NROM. Specifically, the two-bit NROM is capable of storing twice the information as compared to a conventional NROM of equal size. In a two-bit NROM, a left bit and right bit are stored in physically different areas of the charge trapping layer, near the left and right regions. Two-bit memory cell structure is similar to one-bit memory cell with the major difference is the multiple charge trapping centers within the charge trapping layer. Because charge trapping layer is non-conductive, the charges stored in the first and second charge trapping regions remain localized within charge trapping layer, and the state of one charge trapping region does not interfere with the other charge trapping region. Two-bit memory cell thus has four threshold voltage levels, and in such memory cell, the amount of charge trapped in the charge trapping layer is well controlled and each threshold voltage of the memory cell corresponds to a respective value of trapped charge there.

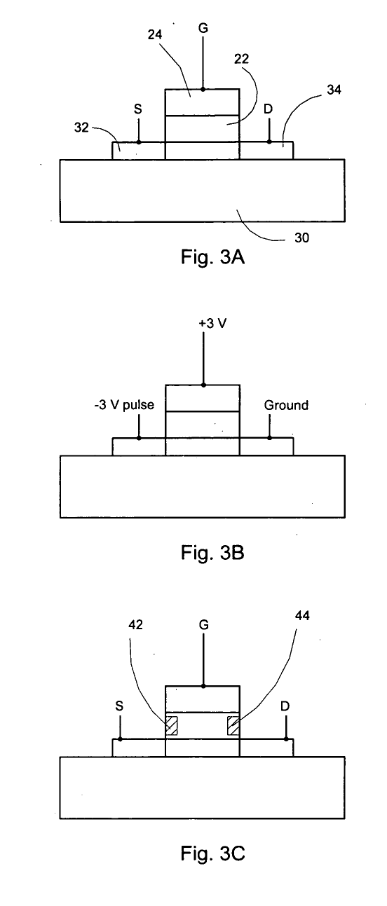

FIG. 3 show the operation of the present invention two-bit charge trapping memory TFT transistor. The TFT memory transistor is similar to the bulk memory transistor of FIG. 2, comprising a gate stack of gate electrode 24 and a charge trapping high-k dielectric layer 22, disposed between the source 32 and drain 34 regions and positioned on an insulator substrate 30. FIG. 3A shows the reset state of the memory transistor with no charge trapped in the high-k dielectric layer, and the memory is in the zero state (0,0). In programming mode (FIG. 3B), when a voltage is applied to the gate electrode 24, and the source and drain are properly biased, the channel between the source and drain is conductive and the charge is accelerated from the source to the drain, and becomes trapped in the gate dielectric. Depending on the sign of the charge, a portion 42 or 44 of the gate dielectric can be charged, resulting in memory state (0,1).

Though two-bit memory cell structure is similar to one-bit memory cell, there are much difficulties for two-bit memory design such as the different thresholds must be clearly distinguishable, not only for the threshold voltage values but also to their statistical distribution since the thresholds cannot be set perfectly. Furthermore, precise fabrication process to achieve narrow statistical distribution of the effective channel length of the two-bit memory must be accomplished to prevent the widening of the distribution of the read currents for each threshold level. Also the gate voltage must be kept very stable to minimize the distribution of read currents since gate voltage variation relates directly to the read current. In addition, since there are multiple levels of read current from multiple thresholds, sensing becomes more complex than in the single bit cell with only two levels.

The present invention single charge trapping layer memory structure can address the multi-bit challenge due to the employment of a single charge trapping layer instead of the triple film ONO stack and the fabrication process can be accomplished without gate spacer formation and is not very sensitive to the location of the drain to channel (or the source to channel) junction, in contrast to various prior art two-bit memory cells designs utilizing twin bit cell flash memory (U.S. Pat. No. 6,538,292 of Chang et al.), floating gate spacer twin-bit memory cell (U.S. Pat. No. 6,551,880 of Lai et al.) and multigate memory cell (U.S. Pat. No. 6,580,124 of Cleeves et al.) which tend to have critical processes of deposition and etching of the charge trapping areas along with the position with respect to the drain/channel or source/channel junctions.

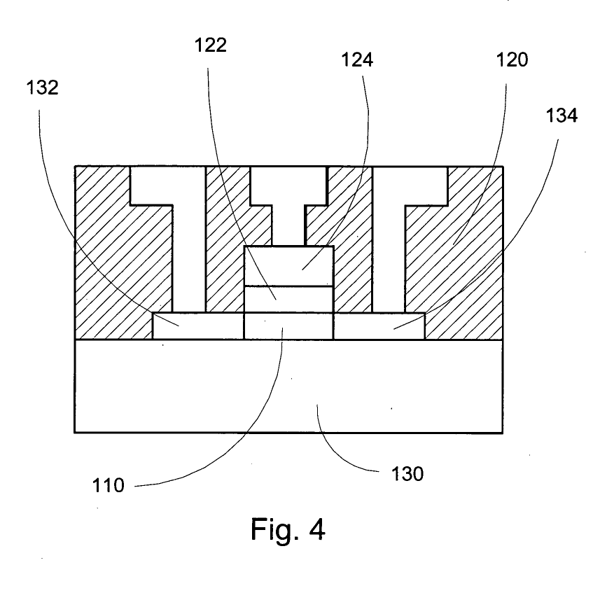

The invention was first demonstrated on thin film transistors consistent with those used in LCD transistor fabrication as shown in FIG. 4. A thin layer (50 nm) of polysilicon 110 on a thick layer of SiO₂ 130 was laser crystallized. The active areas of each transistor were then patterned and etched for isolation of each device. A layer of HfO₂ 122 was deposited by atomic layer deposition (ALD) method to a thickness of about 20 nm. Depending on the deposition condition, a densification anneal may be necessary in order to prevent delamination of the gate in subsequent steps. The anneal is typically about 600° C. for 2 minutes in nitrogen ambient. The film is then exposed to a plasma oxidation process, an ICP plasma generates large qualities of activated oxygen radicals which interacts with the HfO₂ film, converting the film to a highly efficient charge trapping layer. The nature of the charge trapping in such a film is very resilient and will retain its characteristics even in the high temperature anneals. A TiN metal gate electrode 124 is deposited and patterned with the gate mask. This is followed by source 132 and drain 134 implantation, typically an angled implantation performed 4 times with a 90° wafer rotation after each ¼ of the total dose. In the case of the demonstration device, this rotation was not performed so the performance suffered in that symmetrical device performance was not seen for short channel devices. After dopant activation at 750° C. for 2 minutes, the interlayer dielectric TEOS oxide 120 was deposited, contact holes patterned and etched, then fabrication was finished with the metal interconnect layer deposition, pattern and etch.

The high-k dielectric film can be deposited by Chemical Vapor Deposition (CVD), including plasma enhanced chemical vapor deposition (PECVD) and metal organic chemical vapor deposition (MOCVD) or atomic layer deposition (ALD or ALCVD). Chemical Vapor Deposition (CVD) is one of the basic deposition processes of modern semiconductor device structures where a combination of precursor gases or vapors flows over the wafer surface at an elevated temperature. PECVD process is similar to CVD process with the addition of plasma to excite the precursors and lower the deposition temperature. MOCVD process is also CVD process with the use of mostly liquid or solid metal organic precursors.

The high-k dielectric film is preferably deposited by another deposition technology known as atomic layer deposition (ALD or ALCVD) which has markable improvement over CVD technology in terms of gas phase reaction and thin film uniformity. In ALD, the precursor vapors are injected into the process chamber in alternating sequences: precursor, purge gas, reactant, purge gas with the precursor adsorbing onto the substrate and then subsequently reacting with the reactant. There are various modifications of the ALD processes, but the basic ALD processes all contain two distinct properties: alternating injection of precursors and the saturation of the precursor adsorption. In ALD process, a precursor is delivered into the chamber and adsorbed onto the substrate surface. The adsorption temperature is lower than the reaction temperature of CVD process and the adsorbed amount is somewhat less sensitive to the wafer surface temperature. Then the precursor is shut off and a purge gas is delivered into the chamber to purge all the remaining precursor in the chamber volume. A reactant is then delivered into the chamber to react with the adsorbed precursor to form the desired film. Then another purge gas is delivered into the chamber to purge all the remaining reactant vapor in the chamber volume. By alternating precursors and reactants in the vapor stream, the possibility of gas phase reaction is minimized, allowing a wide range of possible precursors not usable with CVD technology. Also because of the adsorption mechanism, the deposited film is extremely uniform because once the surface is saturated, the additional precursors and reactants will not further adsorb or react and will just be exhausted away.

The process patterning and etching of the high-k/electrode gate stack multilayer, contact holes and metal interconnect is preferably by photolithography where a patterned mask is provided on the to-be-patterned substrate layer, then the substrate layer is etched according to the pattern mask, and then the patterned mask is removed. The patterned mask is preferably a photoresist layer, coated and exposed to UV light under a photo mask to transfer a pattern from the photo mask onto the photoresist. The photoresist mask protects the substrate layer during an etch step to transfer the pattern from the photoresist onto the substrate layer. And then the photoresist mask can be stripped. The substrate layer etching is preferably accomplished by reactive ion etching or by wet etches.

Within the scope of the invention, the disclosed single layer charge trapping high-k memory transistor structure may also incorporate other process features such as n-type or p-type bulk substrate, SOI or SIMOX substrate, periphery devices, well formation process, active region threshold voltage adjustment, halo or LDD source and drain, sidewall spacers for the gate stack, shallow trench isolation (STI) or LOCOS isolation, silicide formation such as titanium silicide, cobalt silicide or nickel silicide, raised source and drain, passivation, tungsten or aluminum contact, aluminum or copper metallization.

The device initially was tested for single bit performance where the gate to channel can be pulsed to one polarity to store charge in the charge trapping layer and pulsed in the reverse polarity to erase or reset the device. The ideal programming scheme to utilize the structure is a 2-bit per transistor mode. This is accomplished by addressing the desired bit with a moderated gate voltage (e.g. 3 V) while pulsing either the drain or the source, to use the conventional terms, to a negative voltage of about −3 V for less than 1 ms. This generates a localized charge in the high-k film near the junction that was pulsed. The high effective field between the junction and the gate is sufficient to trap a detectable amount of charge for one of the 2 memory devices. The state of the bit is measured by applying a small voltage (1.5 to 2 V) on the drain (or source) and measure the conductance of the channel. The conductance is influenced by the charge trapped in the high-k film and a sense circuit is able to discern the state of the memory bit. The moderate voltage on the gate is insufficient to affect the state of the memory bit at the other end of the device and measuring the channel conductance from the other end is not influenced by the charge at the opposite end, so there is no disturbance for the two-bit transistor operation.

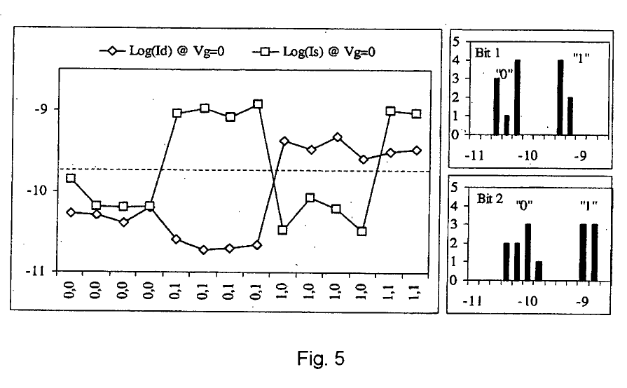

The data for an actual 10 μm×10 μm (length×width) device is shown in FIG. 5 where all combinations for the 2-bit memory states were measured. The contrast between the “0” and “1” can be improved with optimization of the device structure and a larger program fields. Both bits of the transistor can be reset or “0” by applying a negative voltage pulse of approximately −6 V, 1 ms on the gate.

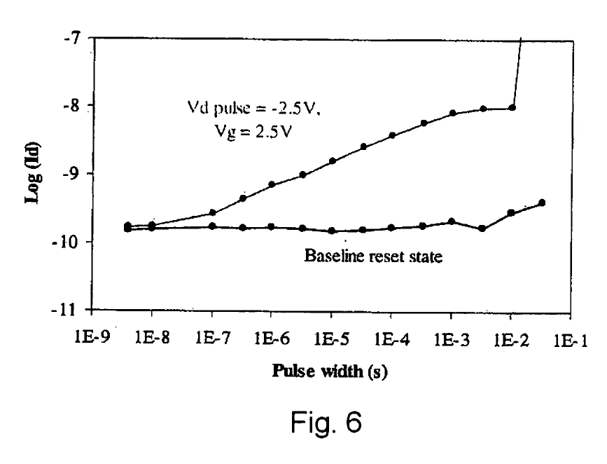

The program pulse width can be as short as 1 μs with the 5 V field as shown in FIG. 6 if the sense circuitry is sensitive enough. With 1 ms pulses, the contrast should be sufficient.

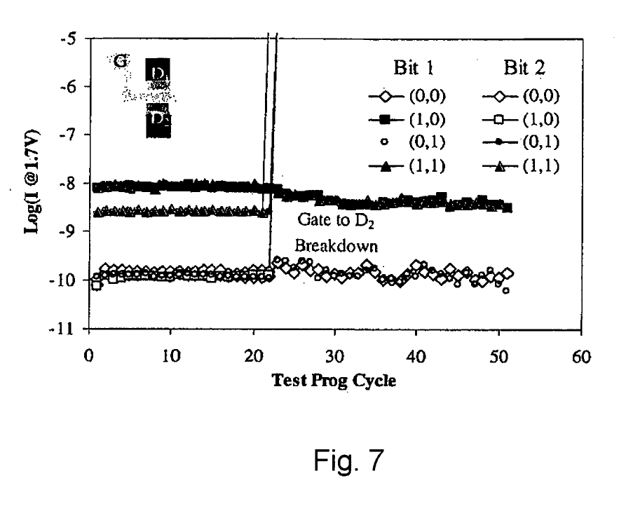

Under an endurance test should one of the bits fail, as in the case shown in FIG. 7 where every possible memory state is tested for each cycle, the opposing bit is seen to be affected slightly but not significantly. The open symbol represent programming to the “0” condition while the filled symbols are for “1”. The clear distinction for bit 1 remains after breakdown of bit 2. In a multi-bit flash EEPROM, a breakdown in the tunnel oxide destroys all bits of that transistor.

Although the fabrication process for the single layer charge trapping transistor is illustrated and described below with reference to certain specific processes, the present invention is nevertheless not intended to be limited to the details shown. The general process of semiconductor fabrication has been practiced for many years, and due to the multitude of different ways of fabricating a device or structure, various modifications may be made in the fabrication process details within the scope and range of the present invention and without departing from the meaning of the invention.

For example, this memory was demonstrated on a TFT structure and TiN metal gate. It can just as easily be performed on silicon on insulator (SOI) substrate, bulk substrate or an insulator substrate (such as glass or plastic) with and high-k dielectric material and any conductive gate electrode such as doped polysilicon, silicide or other metal gate. The demands on the transistor structure are not the key to the performance of this memory. It primarily depends on the single layer charge trap film which is demonstrated to work well with ALD HfO₂ and plasma oxidation. Other high-k dielectric films and other irradiation exposure may work equally well, depending on their charge trapper characteristics with irradiation exposure.

In alternative embodiments, the method can be used to fabricate charge trapping memory cell with pocket implants, for example see Eitan, U.S. Pat. No. 6,030,871 (and its divisions U.S. Pat. No. 6,201,282), and Eitan, U.S. Pat. No. 6,215,148 and its divisions and continuation-in-parts, hereby incorporated by reference. The method can also be used to fabricate charge trapping memory cell with shallow pocket doped regions, for example see Yeh et al., U.S. Pat. No. 6,649,971, hereby incorporated by reference. The memory device can also be used to with symmetrical or asymmetrical charge trapping, for example see Eitan, U.S. Pat. Nos. 6,552,387; 6,011,725; 6,566,699; 5,768,192, hereby incorporated by reference. The memory device can also be subjected to light irradiation such as ultraviolet light to modify the threshold voltage, for example see Pan et al., U.S. Pat. No. 6,576,511, hereby incorporated by reference. The memory device can be designed to preventing antenna effect, for example see Kuo et al., U.S. Pat. No. 6,642,113, hereby incorporated by reference.

1. A single charge trapping layer for storing electrical charge in a memory device comprising a high-k dielectric material.

2. A charge trapping layer as in claim 1 further subjected to a treatment process to improve the charge trapping characteristic.

3. A charge trapping layer as in claim 2 wherein the treatment process is a plasma exposure or an ion implantation exposure.

4. A charge trapping layer as in claim 3 wherein the plasma exposure comprises at least a plasma oxygen exposure, a plasma nitrogen exposure, or a plasma hydrogen exposure.

5. A charge trapping layer as in claim 3 wherein the plasma exposure time is between 10 seconds and 100 seconds.

6. A charge trapping layer as in claim 1 wherein the high-k dielectric material comprises at least one of aluminum oxide (Al₂O₃), hafnium oxide (HfO₂), zirconium oxide (ZrO₂), titanium oxide (TiO₂), tantalum oxide (Ta₂O₅), cesium oxide (CeO₂), lanthanum oxide (La₂O₃), tungsten oxide (WO₃), yttrium oxide (Y₂O₃), bismuth silicon oxide (Bi₄Si₂O₁₂), barium strontium oxide (Ba₁₋ₓSrₓO₃), lanthanum aluminum oxide (LaAlO₃), hafnium silicate (HfSiO₄), zirconium silicate (ZrSiO₄), aluminum hafnium oxide (AlHfO), aluminum oxynitride (AlON), hafnium silicon oxynitride (HfSiON), zirconium silicon oxynitride (ZrSiON), barium titanate (BaTiO₃), strontium titanate (SrTiO₃), lead titanate (PbTiO₃), barium strontium titanate (BST) (Ba₁₋ₓSrₓTiO₃), lead zirconium titanate, lead lanthanum titanate, bismuth titanate, strontium titanate, lead zirconium titanate (PZT (PbZrₓTi₁₋ₓO₃)) barium zirconium titanate, strontium bismuth tantalate, lead zirconate (PbZrO₃), PZN (PbZnₓNb₁₋ₓO₃), PST (PbScₓTa₁₋ₓO₃), or PMN (PbMgₓNb₁₋ₓO3).

7. A non-volatile memory transistor comprising:
source and drain regions provided in a substrate; and
a gate structure on the substrate between the source and drain regions, the gate structure comprising
a single charge trapping layer overlying the substrate, the charge trapping layer comprising a high-k dielectric material; and
an electrode layer overlying the charge trapping layer.

8. A memory transistor as in claim 7 wherein the high-k dielectric material comprises at least hafnium oxide (HfO₂).

9. A memory transistor as in claim 7 wherein the high-k dielectric material comprises at least one of aluminum oxide (Al₂O₃), zirconium oxide (ZrO₂), titanium oxide (TiO₂), tantalum oxide (Ta₂O₅), cesium oxide (CeO₂), lanthanum oxide (La₂O₃), tungsten oxide (WO₃), yttrium oxide (Y₂O₃), bismuth silicon oxide (Bi₄Si₂O₁₂), barium strontium oxide (Ba₁₋ₓSrₓO₃), lanthanum aluminum oxide (LaAlO₃), hafnium silicate (HfSiO₄), zirconium silicate (ZrSiO₄), aluminum hafnium oxide (AlHfO), aluminum oxynitride (AlON), hafnium silicon oxynitride (HfSiON), zirconium silicon oxynitride (ZrSiON), barium titanate (BaTiO₃), strontium titanate (SrTiO₃), lead titanate (PbTiO₃), barium strontium titanate (BST) (Ba₁₋ₓSrₓTiO₃), lead zirconium titanate, lead lanthanum titanate, bismuth titanate, strontium titanate, lead zirconium titanate (PZT (PbZrₓTi₁₋ₓO₃)) barium zirconium titanate, strontium bismuth tantalate, lead zirconate (PbZrO₃), PZN (PbZnₓNb₁₋ₓO₃), PST (PbScₓTa₁₋ₓO₃), or PMN (PbMgₓNb₁₋ₓO3).

10. A memory transistor as in claim 7 wherein the charge trapping layer is subjected to a treatment process to improve the charge trapping characteristic.

11. A charge trapping layer as in claim 10 wherein the treatment process is a plasma exposure or an ion implantation exposure.

12. A charge trapping layer as in claim 111 wherein the plasma exposure comprises at least a plasma oxygen exposure, a plasma nitrogen exposure, or a plasma hydrogen exposure.

13. A charge trapping layer as in claim 11 wherein the plasma exposure time is between 10 seconds and 100 seconds.

14. A memory transistor as in claim 7 wherein the electrode layer is a layer of doped polysilicon, a layer of silicide, or a layer of metal.

15. A memory transistor as in claim 7 wherein the memory transistor is a multi-bit memory transistor.

16. A method of fabricating a non-volatile memory transistor comprising the steps of:
preparing a semiconductor substrate;
forming a gate stack on the substrate, the gate stack comprising
a single charge trapping layer overlying the substrate wherein the charge trapping layer comprises a high-k dielectric material; and
an electrode layer overlying the charge trapping layer; and
forming drain and source regions on opposite sides of the gate stack.

17. A method as in claim 16 wherein the high-k dielectric material comprises at least one of aluminum oxide (Al₂O₃), hafnium oxide (HfO₂), zirconium oxide (ZrO₂), titanium oxide (TiO₂), tantalum oxide (Ta₂O₅), cesium oxide (CeO₂), lanthanum oxide (La₂O₃), tungsten oxide (WO₃), yttrium oxide (Y₂O₃), bismuth silicon oxide (Bi₄Si₂O₁₂), barium strontium oxide (Ba₁₋ₓSrₓO₃), lanthanum aluminum oxide (LaAlO₃), hafnium silicate (HfSiO₄), zirconium silicate (ZrSiO₄), aluminum hafnium oxide (AlHfO), aluminum oxynitride (AlON), hafnium silicon oxynitride (HfSiON), zirconium silicon oxynitride (ZrSiON), barium titanate (BaTiO₃), strontium titanate (SrTiO₃), lead titanate (PbTiO₃), barium strontium titanate (BST) (Ba₁₋ₓSrₓTiO₃), lead zirconium titanate, lead lanthanum titanate, bismuth titanate, strontium titanate, lead zirconium titanate (PZT (PbZrₓTi₁₋ₓO₃)) barium zirconium titanate, strontium bismuth tantalate, lead zirconate (PbZrO₃), PZN (PbZnₓNb₁₋ₓO3), PST (PbScₓTa₁₋ₓO₃), or PMN (PbMgₓNb₁₋ₓO3).

18. A method as in claim 16 wherein the charge trapping layer is subjected to a treatment process to improve the charge trapping characteristic.

19. A method as in claim 18 wherein the treatment process is a plasma exposure or an ion implantation exposure.

20. A method as in claim 19 wherein the plasma exposure comprises at least a plasma oxygen exposure, a plasma nitrogen exposure, or a plasma hydrogen exposure.

21. A method as in claim 19 wherein the plasma exposure time is between 10 seconds and 100 seconds.

22. A method as in claim 16 wherein the charge trapping layer is deposited by ALD method.

23. A method as in claim 16 further comprising a densification anneal step after deposition of the charge trapping layer.

24. A method as in claim 16 wherein the formation of the drain and source regions comprises an angle source and drain implantation.

25. A method as in claim 16 wherein the semiconductor substrate is selected from a group consisted of SOI substrate, bulk silicon substrate, and insulator substrate.

26. A method as in claim 16 wherein the memory transistor is a multi-bit memory transistor.
